(19) United States
(12) Patent Application Publication
(10) Pub. No.: US 2021/0287939 A1
(43) Pub. Date: Sep. 16, 2021

(54) Metal Deposition Processes

(71) Applicant: Fujifilm Electronic Materials U.S.A., Inc., N. Kingstown, RI (US)

(72) Inventor: Sanjay Malik, Attleboro, MA (US)

(21) Appl. No.: 17/195,737

(22) Filed: Mar. 9, 2021

Related U.S. Application Data
(60) Provisional application No. 62/987,500, filed on Mar. 10, 2020.

(51) Int. Cl. H01L 21/768; H01L 21/027; H01L 21/48

(52) U.S. Cl. CPC H01L 21/76877; H01L 21/486; H01L 21/0274; H01L 21/76802

(57) ABSTRACT

This disclosure relates to process for depositing a conducting metal into a trench or hole, in which the trench or hole is surrounded by a dielectric film. The process includes a) providing a dielectric film; b) depositing a resist layer on top of the dielectric film; c) patterning the resist layer to form a trench or hole using actinic radiation or an electron beam or x-ray; d) transferring the pattern created in the resist layer to the underlying dielectric film by etching; and e) filling the created pattern in the dielectric film with a conducting metal to form a dielectric film having a conducting metal filled trench or a conducting metal filled hole.

### CROSS-REFERENCE TO RELATED APPLICATION

The present application claims priority to U.S. Provisional Application Ser. No. 62/987,500, filed on Mar. 10, 2020, the contents of which are hereby incorporated by reference in their entirety.

### BACKGROUND OF THE DISCLOSURE

Dielectric material requirements for semiconductor packaging applications are continuously evolving. The trend in electronic packaging continues to be towards faster processing speeds, increased complexity and higher packing density while maintaining high level of reliability. Current and future packaging architectures include up to 10 redistribution layers and ultra-small features sizes to support high packing density. These features include the width and spacing of metal lines and the spacing and diameter of metal contact vias.

Lithographic processes are employed to define patterns for interconnecting lines and vias. A traditional method for forming metal lines and vias involves patterning a photosensitive dielectric material followed by coating and patterning a photoresist material over the dielectric layer, depositing conducting metal into the patterns and removing the photoresist. This semi additive process can be repeated multiple times to form multilevel interconnections.

Significant drawbacks exist for the semi additive process as removal of the photoresist adds to the complexity and cost of fabrication process. Moreover, the dimension of the resulting lines and vias is limited by the resolution of the photoresist and that of photosensitive dielectric material. In recent years this resolution limit has been diminishing however it is still extremely difficult to pattern a dielectric material at features of less than 2 μm.

Another major drawback of the current generation of photosensitive or photopatternable dielectric materials is their relatively high dielectric loss (Df) due to high concentration of polar functional groups essential to impart patternability. It is well known as the space between the conducting wires is reduced, devices become more susceptible to electrical failures. It is therefore critical to select materials with exceptionally low dielectric loss (Df). Ideal Df values for the next generation materials need to be less than 0.004 in order to properly insulate the ultrafine conducting features and provide high reliability for the device. However, typical materials with ultralow Df values possess very few to no polar functional groups rendering them unsuitable for producing ultrafine patterns under typical lithographic processes.

### SUMMARY OF THE DISCLOSURE

This disclosure describes a process for creating fine or ultrafine (e.g., below 2000 nm) conducting lines embedded in a dielectric film. This process utilizes a resist layer (which can include a high resolution refractory metal resist (RMR) layer and/or a silicon containing resist layer) on top of a dielectric layer. Key characteristics of the RMR layer or a silicon containing resist layer include high resolution owing to high transparency in the light wavelength range of about 13 nm (EUV) to about 436 nm (g-line) and a low dielectric constant (about 2-4). Additionally, the RMR layer or the silicon containing resist layer possesses high etch selectivity relative to a dielectric film, thereby enabling effective transfer of sub-micron patterns into the dielectric film. The RMR layer or the silicon containing resist layer has excellent stability to chemicals typically used in plating processes. Thus, fine or ultrafine conducting metal lines can be subsequently deposited into the underlying dielectric film. Unlike traditional plating resists, the RMR or the silicon containing resist layer does not need to be removed since the RMR or the silicon containing resist themselves are dielectric materials.

In general, this disclosure provides a process for fabricating fine or ultrafine interconnecting lines and vias. This process involves depositing a conducting metal into fine or ultrafine trenches and holes, where the trenches and holes are surrounded by a dielectric film.

In some embodiments, the process includes the steps of:

a) providing a dielectric film;

b) depositing on top of the dielectric film a resist layer selected from the group consisting of a refractory metal resist (RMR) layer and a silicon containing resist layer;

c) patterning the resist layer to form a pattern having a trench or hole using actinic radiation or an electron beam or x-ray;

d) transferring the pattern created in the resist layer to the underlying dielectric film by etching; and

e) filling the created pattern in the dielectric film with a conducting metal to form a dielectric film having a conducting metal filled trench or a conducting metal filled hole.

In some embodiments, the process includes the steps of:

a) providing a dry film comprising a carrier substrate, a resist layer selected from the group consisting of a refractory metal resist (RMR) layer and a silicon containing resist layer, and a dielectric film, wherein the resist layer is between the carrier substrate and the dielectric film;

b) laminating the dry film onto a semiconductor substrate such that the dielectric film is between the semiconductor substrate and the resist layer;

c) removing the carrier substrate;

d) patterning the resist layer to form a pattern having a trench or hole using actinic radiation or an electron beam or x-ray;

e) transferring the pattern created in the resist layer to the underlying dielectric film by etching; and

f) filling the created pattern in the dielectric film with a conducting metal to form a dielectric film having a conducting metal filled trench or a conducting metal filled hole.

Embodiments can include one or more of the following features.

In some embodiments, the trench or hole has a dimension of at most about 10 microns (e.g., at most about 2 microns or at most about 0.5 microns).

In some embodiments, the process further includes forming a multi-stacked structure comprising the dielectric film having a conducting metal filled trench or a conducting metal filled hole.

In some embodiments, the dielectric film has a dielectric loss of at most about 0.004.

In some embodiments, the resist layer is patterned in the light wavelength range of from about 13 nm to about 436 nm.

In some embodiments, the process does not remove the resist layer.

In some embodiments, the dielectric film includes at least one polymer having a dielectric constant of at most about 4 and a dielectric loss of at most about 0.004.

In some embodiments, the refractory metal resist layer is prepared from a composition including a) at least one a metal-containing (meth)acrylate compound; b) at least one solvent; and c) at least one initiator.

In some embodiments, the silicon containing resist layer is prepared from a composition including a) at least one silicon containing polymer; b) at least one solvent; and c) at least one photoacid generator (PAG).

In some embodiments, the resist layer is patterned by contact printing, stepper, scanner, laser direct imaging (LDI), or laser ablation.

### DETAILED DESCRIPTION OF THE DISCLOSURE

As defined herein, unless otherwise noted, all percentages expressed should be understood to be percentages by weight to the total weight of a composition. Unless otherwise noted, ambient temperature is defined to be between about 16 and about 27 degrees Celsius (° C.). As used herein, the terms “layer” and “film” are used interchangeably.

As used herein, the term “ultrafine trenches” or “ultrafine holes” means trenches or holes with a dimension (e.g., a width, a length, or a depth) of at most about 2000 nanometers (e.g., at most about 1500 nm, at most about 1000 nm, at most about 900 nm, at most about 800 nm, at most 700 nm, at most about 600 nm, or at most about 500 nm). As used herein, the term “fine trenches” or “fine holes” means trenches or holes with a dimension (e.g., a width, a length, or a depth) of at most about 10 μm (e.g., at most about 9 μm, at most about 8 μm, at most about 7 μm, at most about 6 μm, at most about 5 μm, at most about 4 μm, or at most about 3 μm).

As used herein, ultralow dielectric loss means dielectric loss of at most about 0.004 (e.g., at most about 0.002, at most about 0.001, at most about 0.0009, at most about 0.0008, at most about 0.0006, at most about 0.0005, at most about 0.0004, or at most about 0.0002).

Some embodiments of this disclosure describe a process of:

a) providing a dielectric film (e.g., on a semiconductor substrate);

b) depositing on top of the dielectric film a resist layer selected from the group consisting of a refractory metal resist (RMR) layer and a silicon containing resist layer;

c) patterning the resist layer to form a pattern having a trench or hole (e.g., a fine or ultrafine trench or hole) using actinic radiation or an electron beam or x-ray;

d) transferring the pattern created in the resist layer to the underlying dielectric film by etching; and

e) filling the created pattern in the dielectric film with a conducting metal to form a dielectric film having a conducting metal filled trench or a conducting metal filled hole.

In some embodiments, the dielectric film in this disclosure is a polymeric film having a dielectric constant of at most about 4 (e.g., at most about 3.8, at most about 3.6, at most about 3.4, or at most about 3.2) and/or at least about 2 (e.g. at least about 2.2, at least about 2.4, at least about 2.6, or at least about 2.8). In some embodiments, the dielectric film in this disclosure or the dielectric polymer in the dielectric film has a dielectric loss of at most about 0.004 (e.g. at most about 0.003, at most about 0.002 or at most about 0.001, at most about 0.0009, at most about 0.0008, at most about 0.0006, at most about 0.0004, or at most about 0.0002) and/or at least about 0.0001 (e.g., at least about 0.0002, at least about 0.0004, at least about 0.0006, at least about 0.0008, or at least about 0.0009).

In some embodiments, the dielectric film of this disclosure can be prepared from a dielectric film forming composition containing at least one dielectric polymer. This composition can be photosensitive or non-photosensitive. The dielectric polymer can be a thermoset or a thermoplastic polymer. The dielectric film forming composition can optionally have one or more other components such as catalysts, initiators, crosslinkers, adhesion promoters, surfactants, plasticizers, corrosion inhibitors, dyes, colorants, inorganic fillers, and organic fillers. Catalysts and initiators can be photosensitive or thermally sensitive.

In some embodiments, the dielectric polymer is selected from the group consisting of polyimides, polyimide precursor polymers, polybenzoxazoles, polybenzoxazole precursor polymers, polyamideimides, (meth)acrylate polymers, epoxy polymers, polyurethanes, polyamides, polyesters, polyethers, novolac resins, polycycloolefins, polyisoprene, polyphenols, polyolefins, benzocyclobutene resins, diamondoids, polystyrenes, polycarbonates, cyanate ester resins, polysiloxanes, copolymers and mixtures thereof. It should be understood that co-, ter-, tetra-polymers and the like can be similarly used (e.g., polystyrene-co-butadiene).

In some embodiments, a dielectric film is prepared from a dielectric film forming composition of this disclosure by a process containing the steps of:

a) coating the dielectric film forming composition described herein on a substrate to form a dielectric film; and

b) optionally baking the dielectric film at a temperature from about 50° C. to about 150° C. for about 20 seconds to about 600 seconds.

Coating methods for preparation of the dielectric film include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating, and (12) lamination of dry film. In case of (1)-(11), the dielectric film forming composition is typically provided in the form of a solution. One skilled in the art would choose the appropriate solvent type and solvent concentration based on the coating type.

Substrates (e.g., semiconductor substrates) can have circular, square, or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can have surface mounted or embedded chips, dyes, or packages. Substrates can be sputtered or pre-coated with a combination of seed layer and passivation layer.

In some embodiments, the substrate can be a carrier substrate used to make a dry film. In such embodiments, the substrate can be flexible and can be a polymer film (such as a polyimide, PEEK, polycarbonate, or polyester film).

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns, at most about 60 microns, at most about 50 microns, at most about 40 microns, or at most about 30 microns), In some embodiments, the dielectric film has a film thickness of at most about 5 microns (e.g., at most about 4.5 microns, at most about 4 microns, at most about 3.5 microns, at most about 3 microns, at most about 2.5 microns, or at most about 2 microns).

In some embodiments, the refractory metal resist (RMR) layer described herein can be prepared from an RMR forming composition containing: a) at least one metal-containing (meth)acrylate compound; b) at least one initiator; and c) at least one solvent. As used herein, the term “(meth)acrylate” include both acrylate compounds and methacrylate compounds. In some embodiments, the RMR forming composition can optionally have one or more other components such as catalysts, initiators, crosslinkers, adhesion promoters, surfactants, plasticizers, corrosion inhibitors, dyes, colorants, inorganic fillers, and organic fillers.

Metal-containing (meth)acrylates (MCAs) of the present disclosure can be represented by Structure I:

MR¹ₓR²_{y} (Structure I)

in which each R¹ is independently a (meth)acrylate-containing organic group; each R² is independently selected from a group consisting of alkoxide, thiolate, alkyl, aryl, carboxyl, β-diketonate, cyclopentadienyl and oxo; x is 1, 2, 3, or 4, y is 0, 1, 2, or 3, and x+y=4; and M is Ti, Zr or Hf.

Suitable metal atoms (M) useful for the MCAs in the present disclosure include titanium, zirconium, and hafnium.

Suitable examples of (meth)acrylate-containing organic groups (R¹) include, but are not limited to, (meth)acrylate, carboxyethyl (meth)acrylate, and 2-hydroxyethyl (meth)acrylate.

Suitable examples of R² include, but are not limited to, ethoxide, 1-propoxide, 2-propoxide, 1-butoxide, 2-butoxide, 1-pentoxide, 2-ethylhexoxide, 1-methyl-2-propoxide, 2-methoxyethoxide, 2-ethoxyethoxide, 4-methyl-2-pentoxide, 2-propoxyethoxide, and 2-butoxyethoxide, methyl thiolate, neopentyl, phenyl, cyclopentadiene, and oxygen.

Examples of suitable MCAs include, but are not limited to, titanium tetra(meth)acrylate, zirconium tetra(meth)acrylate, hafnium tetra(meth)acrylate, titanium butoxide tri(meth)acrylate, titanium (meth)acryloxyethylacetoacetate triisopropoxide, titanium tris(2-ethylhexanoate) (carboxyethyl (meth)acrylate), titanium dibutoxide di(meth)acrylate, titanium tributoxide (meth)acrylate, titanium oxide di(meth)acrylate, zirconium butoxide tri(meth)acrylate, zirconium dibutoxide di(meth)acrylate, zirconium tributoxide (meth)acrylate, zirconium oxide di(meth)acrylate, hafnium butoxide tri(meth)acrylate, hafnium dibutoxide di(meth)acrylate, hafnium tributoxide (meth)acrylate, hafnium oxide di(meth)acrylate, titanium (2,4-pentanedionate) tri(carboxyethyl (meth)acrylate), titanium tetra(carboxyethyl (meth)acrylate), zirconium tetra(carboxyethyl (meth)acrylate), hafnium tetra(carboxyethyl (meth)acrylate), titanium butoxide tri(carboxyethyl (meth)acrylate), titanium dibutoxide di(carboxyethyl (meth)acrylate), titanium tributoxide (carboxyethyl (meth)acrylate), titanium oxide di(carboxyethyl (meth)acrylate), zirconium butoxide tri(carboxyethyl (meth)acrylate), zirconium dibutoxide di(carboxyethyl (meth)acrylate), zirconium tributoxide (carboxyethyl (meth)acrylate), zirconium oxide di(carboxyethyl (meth)acrylate), zirconium bis(2-ethylhexanoate) di(carboxyethyl (meth)acrylate), zirconium bis(2,4-pentanedionate) di(carboxyethyl (meth)acrylate), hafnium butoxide tri(carboxyethyl (meth)acrylate), hafnium dibutoxide di(carboxyethyl (meth)acrylate), hafnium tributoxide (carboxyethyl (meth)acrylate) or hafnium oxide di(carboxyethyl (meth)acrylate).

In general, the (meth)acrylate groups of the MCAs are sufficiently reactive to enable the MCAs to participate in crosslinking of the RMR layer induced by free radicals, which can be generated by one or more initiators present in the RMR forming composition. The crosslinking or polymerization can occur between at least two MCAs or between at least one MCA and at least one non-MCA crosslinker in the RMR forming composition.

In some embodiments, the amount of the metal-containing (meth)acrylate compound (MCAs) is at least about 2 weight % (e.g. at least about 5 weight %, at least about 10 weight %, at least about 15 weight %, at least about 20 weight %, or at least about 25 weight %) and/or at most about 60 weight % (e.g., at most about 55 weight %, at least about 50 weight % at least about 45 weight %, at least about 40 weight %, or at most about 35 weight %) of the entire weight of the RMR forming composition.

The solvent and concentration in the RMR forming composition can be selected based upon the coating method and MCA solubility. Specific examples of solvents include, but are not limited to, acetone, 2-butanone, 3-methyl-2-butanone, 4-hydroxy-4-methyl-2-pentanone, 4-methyl-2-pentanone, 2-heptanone, cyclopentanone, cyclohexanone, 1-methoxy-2-propanol, 2-methoxyethanol, 2-ethoxyethanol, ethylene glycol monoisopropyl ether, 2-propoxyethanol, 2-butoxyethanol, 4-methyl-2-pentanol, tripropylene glycol, tetraethylene glycol, 2-ethoxyethyl ether, 2-butoxyethyl ether, diethylene glycol dimethyl ether, cyclopentyl methyl ether, 1-methoxy-2-propyl acetate, 2-ethoxyethyl acetate, 1,2-dimethoxy ethane ethyl acetate, cellosolve acetate, methyl lactate, ethyl lactate, ethyl acetate, propyl acetate, n-butyl acetate, methyl pyruvate, ethyl pyruvate, methyl 3-methoxypropionate, ethyl 3-methoxypropionate, γ-butyrolactone, propylene carbonate, butylene carbonate, tetrahydrofuran, 2-methyl tetrahydrofuran, tetrahydrofufuryl alcohol, N-methyl-2-pyrrolidone, dimethyl formamide, dimethyl sulfoxide, diacetone alcohol, 1,4-dioxane, methanol, ethanol, 1-propanol, 2-propanol, and 1-butanol.

In some embodiments, the amount of the solvent is at least about 40 weight % (e.g., at least about 45 weight %, at least about 50 weight %, at least about 55 weight %, at least about 60 weight %, or at least about 65 weight %) and/or at most about 98 weight % (e.g., at most about 95 weight %, at most about 90 weight %, at most about 85 weight %, at most about 80 weight %, or at most about 75 weight %) of the entire weight of the RMR forming composition.

The initiator in the RMR forming composition can be a photoinitiator or a thermal initiator. Specific examples of photoinitiators include, but are not limited to, 1,8-octanedione, 1,8-bis[9-(2-ethylhexyl)-6-nitro-9H-carbazol-3-yl]-1,8-bis(O-acetyloxime), 2-hydroxy-2-methyl-1-phenylpropan-1-one, 1-hydroxycyclohexyl phenyl ketone (Irgacure 184 from BASF), a blend of 1-hydroxycyclohexylphenylketone and benzophenone (Irgacure 500 from BASF), 2,4,4-trimethylpentyl phosphine oxide (Irgacure 1800, 1850, and 1700 from BASF), 2,2-dimethoxyl-2-acetophenone (Irgacure 651 from BASF), bis(2,4,6-trimethyl benzoyl)phenyl phosphine oxide (Irgacure 819 from BASF), 2-methyl-1-[4-(methylthio)phenyl]-2-morphorinopropane-1-on (Irgacure 907 from BASF), (2,4,6-trimethylbenzoyl)diphenyl phosphine oxide (Lucerin TPO from BASF), 2-(Benzoyloxyimino)-1-[4-(phenylthio)phenyl]-1-octanone (Irgacure OXE-01 from BASF), 1-[9-Ethyl-6-(2-methylbenzoyl)-9H-carbazol-3-yl]ethanone 1-(O-acetyloxime) (Irgacure OXE-2 from BASF), ethoxy(2,4,6-trimethylbenzoyl)phenyl phosphine oxide (Lucerin TPO-L from BASF), a blend of phosphine oxide, hydroxy ketone and a benzophenone derivative (ESACURE KT046 from Arkema), 2-hydroxy-2-methyl-1-phenylpropane-1-on (Darocur 1173 from Merck), NCI-831 (ADEKA Corp.), NCI-930 (ADEKA Corp.), N-1919 (ADEKA Corp.), benzophenone, 2-chlorothioxanthone, 2-methylthioxanthone, 2-isopropylthioxanthone, benzodimethyl ketal, 1,1,1-trichloroacetophenone, diethoxyacetophenone, m-chloroacetophenone, propiophenone, anthraquinone, dibenzosuberone and the like.

In some embodiments, a photosensitizer can be used in the RMR forming composition where the photosensitizer can absorb light in the wavelength range of 193 to 405 nm. Examples of photosensitizers include, but are not limited to, 9-methylanthracene, anthracenemethanol, acenaphthylene, thioxanthone, methyl-2-naphthyl ketone, 4-acetylbiphenyl, and 1,2-benzofluorene.

Specific examples of thermal initiators include, but are not limited to, benzoyl peroxide, cyclohexanone peroxide, lauroyl peroxide, tert-amyl peroxybenzoate, tert-butyl hydroperoxide, di(tert-butyl)peroxide, dicumyl peroxide, cumene hydroperoxide, succinic acid peroxide, di(n-propyl)peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, the amount of the initiator is at least about 0.1 weight % (e.g., at least about 0.2 weight %, at least about 0.5 weight %, at least about 1 weight %, at least about 2 weight %, or at least about 3 weight %) and/or at most about 10 weight % (e.g., at most about 9 weight %, at most about 8 weight %, at most about 7 weight %, at most about 6 weight %, or at most about 5 weight %) of the entire weight of the RMR forming composition.

In some embodiments, the silicon containing resist layer described herein can be prepared from a silicon containing resist forming composition containing a) at least one silicon containing polymer; b) at least one solvent (such as those described herein); and c) at least one photoacid generator (PAG).

Any suitable photoacid generators, particularly nitrobenzyl esters and onium sulfonate salts, which generate acid under the effects of active radiation from exposure sources ranging from election beam, ArF excimer lasers and KrF excimer lasers, can be used together with the silicon containing polymers described herein to prepare radiation-sensitive photoresist compositions.

Suitable onium sulfonate salts can include aryl sulfonium and iodonium sulfonates, especially triaryl sulfonium and iodonium sulfonates. The aryl groups of the sulfonium or iodonium moieties may be substituted or unsubstituted aryl groups, such as phenyl or naphthyl, each of which is optionally substituted by one or more substituents such as halogen, C₁₋₄ alkyl, C₁₋₄ alkoxy, —OH, and/or nitro substituents. The aryl groups or substituents on each aryl group may be the same or different.

The anion of the photoacid generator can be any suitable anion of a suitable organic sulfonic acid, such as aliphatic, cycloaliphatic, carbocyclic-aromatic, heterocyclic-aromatic or arylaliphatic sulfonic acids. These anions can be substituted or unsubstituted. Partially fluorinated or perfluorinated sulfonic acid derivatives or sulfonic acid derivatives substituted in the neighboring position to the respective acid group are preferred. Examples of substituents include halogens (e.g., F or Cl), alkyl (e.g., methyl, ethyl, or n-propyl), and alkoxy (e.g., methoxy, ethoxy, or n-propoxy).

Preferably, the anion of the photoacid generator is a monovalent anion from a partially fluorinated or perfluorinated sulfonic acid, such as fluorinated alkyl sulfonate anions.

Specific examples of suitable onium salts include triphenyl sulfonium bromide, triphenyl sulfonium chloride, triphenyl sulfonium iodide, triphenylsulfonium methane sulfonate, triphenylsulfonium trifluoromethane sulfonate, triphenylsulfonium hexafluoro-propane sulfonate, triphenylsulfonium nonafluorobutane sulfonate, triphenylsulfonium phenyl sulfonate, triphenylsulfonium 4-methylphenyl sulfonate, triphenylsulfonium 4-methoxyphenyl sulfonate, triphenylsulfonium 4-chlorophenyl sulfonate, triphenyl-sulfonium camphorsulfonate, 4-methylphenyl-diphenylsulfonium trifluoromethane sulfonate, bis(4-methylphenyl)-phenylsulfonium trifluoromethane sulfonate, tris-4- methylphenylsulfonium trifluoromethane sulfonate, 4-tert-butylphenyl-diphenylsulfonium trifluoromethane sulfonate, 4-methoxyphenyl-diphenylsulfonium trifluoromethane sulfonate, mesityl-diphenylsulfonium trifluoromethane sulfonate, 4-chlorophenyldiphenyl-sulfonium trifluoromethane sulfonate, bis-(4-chlorophenyl)-phenylsulfonium trifluoro-methane sulfonate, tris-(4-chlorophenyl) sulfonium trifluoromethane sulfonate, 4-methyl-phenyl-diphenylsulfonium hexafluoropropane sulfonate, bis(4-methylphenyl)-phenyl-sulfonium hexafluoropropane sulfonate, tris-4-methylphenylsulfonium hexafluoro-propane sulfonate, 4-tert-butylphenyl-diphenylsulfonium hexafluoropropane sulfonate, 4-methoxyphenyl-diphenylsulfonium hexafluoropropane sulfonate, mesityl-diphenyl-sulfonium hexafluoropropane sulfonate, mesityl-diphenylsulfonium nonafluorooctane sulfonate, mesityl-diphenylsulfonium perfluorobutane sulfonate, 4-chlorophenyl-diphenylsulfonium hexafluoropropane sulfonate, bis-(4-chlorophenyl)-phenylsulfonium hexafluoropropane sulfonate, tris-(4-chlorophenyl) sulfonium hexafluoropropane sulfonate, diphenyliodonium trifluoromethane sulfonate, diphenyliodonium hexafluoropropane sulfonate, diphenyliodonium 4-methylphenyl sulfonate, bis-(4-tert-butylphenyl)iodonium trifluoromethane sulfonate, bis-(4-tert-butyl-phenyl)iodonium hexafluoropropane sulfonate, bis-(4-cyclohexylphenyl)iodonium trifluoromethane sulfonate, tris(4-tert-butylphenyl)sulfonium perfluorooctane sulfonate, and bis-(4-cyclohexylphenyl)iodonium hexafluoropropane sulfonate. A preferred example is triphenyl sulfonium trifluoromethane sulfonate (triphenyl sulfonium triflate).

In some embodiments, the amount of the PAG is at least about 0.1 weight % (e.g., at least about 0.2 weight %, at least about 0.5 weight %, at least about 1 weight %, at least about 2 weight %, or at least about 3 weight %) and/or at most about 10 weight % (e.g., at most about 9 weight %, at most about 8 weight %, at most about 7 weight %, at most about 6 weight %, at most about 5 weight %, at most about 4 weight %, at most about 3 weight %, at most about 2 weight %, or at most about 1 weight %) of the entire weight of the silicon containing resist forming composition.

An example of the silicon containing polymer is a tetrapolymer containing the following four monomer repeating units:

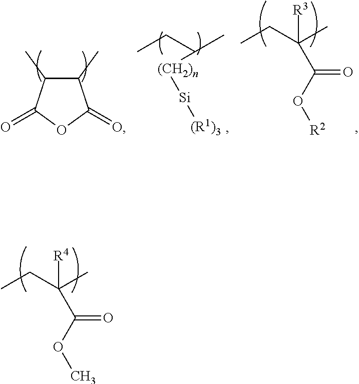

wherein n is an integer of 1 to 5, R¹ is a methyl or trimethylsiloxy group; R² is a tert-butyl group; and R³ and R⁴ are each independently selected from hydrogen or a methyl group. Preferably, n is equal to 1.

In some embodiments, the silicon containing polymer can be prepared by polymerization of one or more of the following monomers:

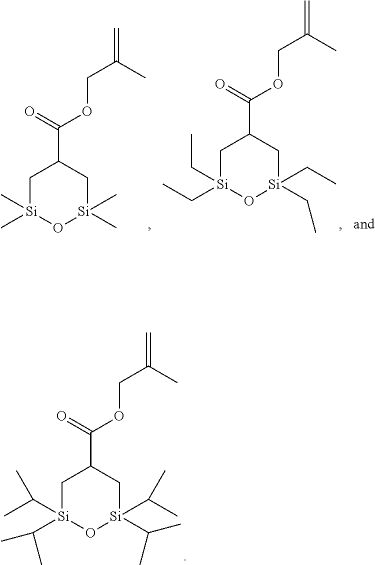 [SMILES: C=C(C)COC(=O)C1C[Si](C)(C)O[Si](C)(C)C1 ; C=C(C)COC(=O)C1C[Si](CC)(CC)O[Si](CC)(CC)C1 ; C=C(C)COC(=O)C1C[Si](C(C)C)(C(C)C)O[Si](C(C)C)(C(C)C)C1]

Other examples of suitable silicon containing polymers are described in U.S. Pat. Nos. 6,929,897, 6,916,543 and 6,165,682, which are incorporated herein by reference.

In some embodiments, the amount of the silicon containing polymer is at least about 1 weight % (e.g. at least about 2 weight %, at least about 5 weight %, at least about 8 weight %, at least about 10 weight %, or at least about 12 weight %) and/or at most about 30 weight % (e.g., at most about 27 weight %, at most about 25 weight % at most about 23 weight %, at most about 20 weight %, or at most about 15 weight %) of the entire weight of the silicon containing resist forming composition.

In some embodiments, the amount of the solvent is at least about 60 weight % (e.g., at least about 65 weight %, at least about 70 weight %, at least about 75 weight %, at least about 80 weight %, or at least about 85 weight %) and/or at most about 98 weight % (e.g., at most about 96 weight %, at most about 95 weight %, at most about 94 weight %, at most about 92 weight %, at most about 90 weight %, or at most about 85 weight %) of the entire weight of the silicon containing resist forming composition.

The resist layer can be formed by (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In the cases of (1)-(11), the resist forming composition used to prepare the resist layer is typically provided in the form of a solution. One skilled in the art would choose the appropriate solvent type and solvent concentration based on the coating type.

In some embodiments, the coated resist layer can optionally be baked at a temperature from about 40° C. to about 120° C. for about 1 minute to about 10 minutes.

In some embodiments, the resist layer has a film thickness of at least about 0.1 micron (e.g., at least about 0.2 micron, at least about 0.4 micron, at least about 0.6 micron, or at least about 0.8 micron) and/or at most about 3.0 microns (e.g., at most about 2.5 microns, at most about 2.0 microns, at most about 1.5 microns, or at most about 1.0 micron).

In some embodiments, the resist layer is a dielectric film having a dielectric constant of at most about 4 (e.g., at most about 3.8, at most about 3.6, at most about 3.4, or at most about 3.2) and/or at least about 2 (e.g. at least about 2.2, at least about 2.4, at least about 2.6, or at least about 2.8).

In some embodiment, lamination of a dry film (e.g., a bilayer dry film containing a resist layer (e.g., a RMR layer or a silicon containing resist layer) and a dielectric layer) is used to coat the resist layer and the dielectric layer on a semiconductor substrate. In some embodiments, in order to produce a suitable bilayer dry film, the resist layer (e.g., a RMR or silicon containing resist layer) is first coated and dried on a suitable carrier substrate, followed by coating the dielectric film on top of resist to obtain a bilayer dry film. This bilayer film can then be laminated onto a semiconductor substrate by using lamination processes known to those skilled in the art.

In some embodiments, the lamination temperature used in the lamination process described above is at least about 50° C. (e.g., at least about 55° C., at least about 60° C., at least about 65° C., at least about 70° C., at least about 75° C., or at least about 80° C.) to at most about 120° C. (e.g., at most about 115° C., at most about 110° C., at most about 105° C., at most about 100° C., at most about 95° C., or at most about 90° C.). The carrier substrate can be removed before or after patterning step.

In some embodiments, the carrier substrate is a single or multiple layer plastic film, which optionally has undergone treatment to modify the surface of the film. As specific examples of the carrier substrate, there can be various plastic films such as polyethylene terephthalate (PET), polyethylene naphthalate, polypropylene, polyethylene, cellulose tri-acetate, cellulose di-acetate, poly(metha)acrylic acid alkyl ester, poly(metha)acrylic acid ester copolymer, polyvinylchloride, polyvinyl alcohol, polycarbonate, polystyrene, cellophane, polyvinyl chloride copolymer, polyamide, polyimide, vinyl chloride-vinyl acetate copolymer, polytetrafluoroethylene, polytrifluoroethylene, and the like.

Patterning of the resist layer (e.g., a RMR or silicon containing resist layer) can be achieved by contact printing, stepper, scanner, laser direct imaging (LDI), or laser ablation. In some embodiments, the patterning can be performed by direct exposure to a laser operating in a wavelength in the range of 10,600 nm to 13.5 nm or by exposing to a source of light operating in a range of 436 nm to 13.5 nm through a mask.

After the exposure, the resist layer (e.g., a RMR or silicon containing resist layer) can optionally be heat treated to at least about 50° C. (e.g., at least about 55° C., at least about 60° C., or at least about 65° C.). to at most about 100° C. (e.g., at most about 95° C., or at most about 90° C., at most about 85° C., at most about 80° C., at most about 75° C., or at most about 70° C.) for at least about 60 seconds (e.g., at least about 65 seconds or at least about 70 seconds) to at most about 600 seconds (e.g., at most about 480 seconds, at most about 360 seconds, at most about 240 seconds, at most about 180 seconds, at most about 120 seconds or at most about 90 seconds). The heat treatment is usually accomplished by use of a hot plate or oven.

After the exposure and optional heat treatment, if the resist layer includes a RMR layer, the RMR layer can be developed to remove unexposed portions by using a developer thereby providing a relief pattern. Development can be carried out by, for example, an immersion method or a spraying method. Suitable developers include, but are not limited to, acetone, 2-butanone, 3-methyl-2-butanone, 4-hydroxy-4-methyl-2-pentanone, 4-methyl-2-pentanone, 2-heptanone, cyclopentanone, cyclohexanone, 1-methoxy-2-propanol, 2-methoxyethanol, 2-ethoxyethanol, ethylene glycol monoisopropyl ether, 2-propoxyethanol, 2-butoxyethanol, 4-methyl-2-pentanol, tripropylene glycol, tetraethylene glycol, 2-ethoxyethyl ether, 2-butoxyethyl ether, diethylene glycol dimethyl ether, cyclopentyl methyl ether, 1-methoxy-2-propyl acetate, 2-ethoxyethyl acetate, 1,2-dimethoxy ethane ethyl acetate, cellosolve acetate, methyl lactate, ethyl lactate, ethyl acetate, propyl acetate, n-butyl acetate, methyl pyruvate, ethyl pyruvate, methyl 3-methoxypropionate, ethyl 3-methoxypropionate, γ-butyrolactone, propylene carbonate, butylene carbonate, tetrahydrofuran, 2-methyl tetrahydrofuran, tetrahydrofufuryl alcohol, N-methyl-2-pyrrolidone, dimethyl formamide, dimethyl sulfoxide, diacetone alcohol, 1,4-dioxane, methanol, ethanol, 1-propanol, 2-propanol, and 1-butanol.

If the resist layer includes a silicon containing resist layer, the silicon containing resist layer can alternatively be developed by a dilute solution of tetramethyl ammonium hydroxide (TMAH). Typically, a TMAH solution of normality between 0.5 to 3 is used to provide a relief pattern.

Alternatively, patterning can be achieved by exposing the resist layer (e.g., a RMR or silicon containing resist layer) to a source of electron beam or x-ray. One important aspect of this disclosure is that the resist layer (e.g., a RMR or silicon containing resist layer) can provide relief pattern of high resolution. This allows the creation of fine and ultrafine patterns in the resist layer, which can then be transferred to the dielectric film (e.g., by etching). In some embodiments, the resolution is about 2 μm or less (e.g., about 1.8 μm or less, about 1.6 μm or less, about 1.4 μm or less, about 1.2 μm or less, about 1.0 μm or less, about 0.9 μm or less, about 0.8 μm or less, about 0.7 μm or less, about 0.6 μm or less, about 0.5 μm or less, about 0.4 μm or less, about 0.3 μm or less, about 0.2 μm or less, or about 0.1 μm or less). In other words, the resist layer can be resolved to create patterns with features having a size (e.g., width, length, or depth) of about 2 μm or less.

Transferring of the pattern from the resist layer (e.g., a RMR or silicon containing resist layer) to the dielectric film can be achieved by dry or wet etching. Dry etching can be achieved by reactive ions (RIE) or oxygen, argon, fluorocarbon plasma or a mixture thereof. Wet etching can be achieved by using suitable acids, buffer acids or bases, or solvents, in which the dielectric film is soluble and the resist layer (e.g., a RMR or silicon containing resist layer) is insoluble.

Some embodiments of this disclosure describe the filling of the created patterns in the dielectric film with a conducting metal. In some embodiment, to achieve this, a seed layer conformal to the patterned dielectric film is first deposited on the patterned dielectric film (e.g., outside the openings in the film). Seed layer can contain a barrier layer and a metal seed layer (e.g., a copper seed layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-aspect-ratio) features. The fill factor by sputtering deposition can be improved by collimating the sputtered flux. Typically, this is achieved by inserting between the target and substrate a collimator plate having an array of hexagonal cells.

The next step in the process is metal seeding deposition. A thin metal (e.g., an electrically conductive metal such as copper) seed layer can be formed on top of the barrier layer in order to improve the deposition of the metal layer (e.g., a copper layer) formed in the succeeding step.

The next step in the process is depositing of an electrically conductive metal layer (e.g., a copper layer) on top of the metal seed layer in the openings of the patterned dielectric film wherein the metal layer is sufficiently thick to fill the openings in the patterned dielectric film. The metal layer can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into ultrafine features in the dielectric film. Copper deposition methods generally should meet the stringent requirements of the semiconductor industry. For example, copper deposits should be uniform and capable of flawlessly filling the ultrafine features of the device, for example, with openings of 500 nm or smaller. This technique has been described, e.g., in U.S. Pat. No. 5,891,804 (Havemann et al.). U.S. Pat. No. 6,399,486 (Tsai et al.), and U.S. Pat. NO. 7,303,992 (Paneccasio et al.), the contents of which are hereby incorporated by reference.

In some embodiments, the process described herein can further includes one or more steps to form a multi-stacked structure that includes at least one (e.g., two or three) dielectric film having a conducting metal filled trench or a conducting metal filled hole. For example, the multi-stacked structure can be prepared by repeating the process steps (a)-(e) described above one or more (e.g., two or three) times.

### EXAMPLES

### Preparation of RMR 1

An RMR forming composition was prepared by mixing zirconium carboxyethyl acrylate (30 g), Irgacure® OXE 01 (0.9 g), butanol (20 g), 1-methoxy-2-propanol (18.0 g), and 1-methoxy-2-propyl acetate (31.1 g) to form a homogeneous solution. The solution was filtered by using a 0.2 micron PTFE filter.

### Example 1: Fine and Ultrafine Cu Lines in Polyimide Dielectric

LTC 9320-E07 supplied by Fujifilm Electronic Materials USA containing a polyimide precursor polymer as a dielectric polymer was spin coated on a 100 mm PVD-copper wafer and was baked at 115° C. for 6 minutes on a hot plate to remove most of the solvent. The resulting polyimide precursor dielectric film was flood exposed with an 8 W i-line LED lamp (UVP CL-1000L) at a dose of 600 mJ/cm². After exposure, the crosslinked polyimide precursor dielectric film was imidized at 400° C. for 1 hour under nitrogen to form a film thickness of 3.1 μm, thus providing a dielectric film containing a polyimide polymer. The dielectric constant value of this polyimide polymer was 3.2 and dielectric loss value was 0.02.

RMR 1 was spin coated on top of the dielectric film of this example. The RMR layer was baked at 50° C. for 60 seconds on a hot plate to remove most of the solvent and to complete the preparation of the stack of dielectric film and RMR layer of the example on top of a PVD-copper wafer. The RMR layer was then exposed with a Canon i-line stepper (NA 0.45, SIGMA 0.7) through a trench test pattern reticle 1 at a fixed dose of 500 mJ/cm² and −1.0 μm fixed focus. The exposed RMR layer was then developed by using 1-methoxy-2-propanol as solvent for 10 seconds to resolve trenches of dimensions of 50 μm and below including ultrafine 2 μm trench patterns as observed by an optical microscope. These 2 μm trench patterns were confirmed by cross-sectional scanning electron microscopy (SEM). The thickness of the RMR layer after development was 0.60 μm. The ultrafine trench pattern was transferred to the dielectric film by etching with oxygen plasma for 25 minutes at Rf of 250 W and oxygen gas flow rate of 15 sccm.

The ultrafine trench patterns were then filled by electrodeposition of copper. The electrodeposition of copper was achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating was performed in a beaker while stirring using the following conditions: Anode: Copper; Plating Temperature: 25° C.; Current density: 10 mA/cm²; and Time: 2 minutes.

After completion of the process, copper lines of dimensions 50 μm and below were formed including fine 10 μm and ultrafine 2 μm copper lines in polyimide dielectric film. The dimensions of the fine and ultrafine copper lines were confirmed by optical microscope and cross-sectional SEM.

### Example 2: Ultrafine Cu Lines in Polyimide Dielectric

LTC 9320-E07 supplied by Fujifilm Electronic Materials USA containing a polyimide precursor polymer as a dielectric polymer was spin coated on a 100 mm PVD-copper wafer and was baked at 115° C. for 6 minutes on a hot plate to remove most of the solvent. The resulting polyimide precursor dielectric film was flood exposed with an 8 W i-line LED lamp (UVP CL-1000L) at a dose of 600 mJ/cm². After exposure, the crosslinked polyimide precursor dielectric film was imidized at 400° C. for 1 hour under nitrogen to form a film thickness of 3.2 μm, thus providing a dielectric film containing a polyimide polymer. The dielectric constant value of this polyimide polymer was 3.2 and dielectric loss value was 0.02.

RMR 1 was spin coated on top of the dielectric film of this example. The RMR layer was baked at 50° C. for 60 seconds on a hot plate to remove most of the solvent and to complete the preparation of the stack of dielectric film and RMR layer of the example on top of a PVD-copper wafer. The RMR layer was then exposed with a Canon i-line stepper (NA 0.45, SIGMA 0.7) through a trench test pattern reticle 2 at a fixed dose of 500 mJ/cm² and −1.0 μm fixed focus. The exposed RMR layer was then developed by using 1-methoxy-2-propanol as solvent for 10 seconds to resolve ultrafine trenches of dimensions of 2 μm and below including 700 nm trench patterns as observed by an optical microscope. These 700 nm trench patterns were confirmed by cross-sectional scanning electron microscopy (SEM). The thickness of the RMR layer after development was 0.34 μm. The ultrafine trench pattern was transferred to the dielectric film by etching with oxygen plasma for 25 minutes at Rf of 250 W and oxygen gas flow rate of 15 sccm.

The ultrafine trench patterns were then filled by electrodeposition of copper. The electrodeposition of copper was achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating was performed in a beaker while stirring using the following conditions: Anode: Copper; Plating Temperature: 25° C.; Current density: 10 mA/cm²; and Time: 2 minutes.

After completion of the process, copper lines of dimensions 2 μm and below were formed including ultrafine 700 nm copper lines in polyimide dielectric film. The dimensions of the ultrafine copper lines were confirmed by optical microscope and cross-sectional SEM.

### Preparation of RMR 2

An RMR composition was prepared by mixing zirconium carboxyethyl acrylate (30 g), Irgacure® OXE01 (as an initiator, 0.9 g), butanol (20 g), 1-methoxy-2-propanol (18.0 g) and 1-methoxy-2-propyl acetate (31.1 g), and a solution of 0.015% naphthalene sulfonic salt of Victoria Blue Dye in propylene carbonate (1 g solution) to form a homogeneous solution. The RMR composition was filtered by using a 0.2 micron PTFE filter.

### Example 3: Fine and Ultrafine Cu Lines in Polycycloolefin and Polyolefin Dielectric

This example pertains to a dielectric film based on dielectric polymers with ultralow dielectric loss. Dielectric polymers used in this example were a b-stage methacrylate-functionalized cycloolefin thermoset resin with dielectric constant value of 2.45 and dielectric loss value of 0.0012 and a cyclized rubber with dielectric constant value of 2.4 and dielectric loss value of 0.0002.

A dielectric film forming composition of this example was prepared by mixing a b-stage methacrylate-functionalized cycloolefin thermoset resin (Proxima® supplied by Materia Inc., 10 g), a cyclized rubber (SC Rubber supplied by Fujifilm Electronic Materials U.S.A., 6.7 g), tricyclodecanedimethanol diacrylate (2.5 g), tetraethylene glycol diacrylate (1.7 g), Irgacure® OXE01 (0.5 g), methacryloxypropyltrimethoxysilane (0.8 g), and xylene (51.7 g) to obtain a homogeneous solution. This solution was spin-coated on a 100 mm PVD-copper wafer to form a film. The film was baked at 115° C. for 6 minutes using a hot plate to remove the majority of solvent. The film was flood exposed with an i-line LED lamp (UVP CL-1000L) at a dose of 500 mJ/cm². After exposure, the crosslinked dielectric film was baked at 150° C. for 2 hours under vacuum to achieve a dielectric film with thickness of 3.3 μm.

The b-stage methacrylate-functionalized cycloolefin thermoset resin (Proxima®) and cyclized rubber (SC Rubber) used here were examples of polycycloolefin and polyolefin dielectric polymers. Tricyclodecanedimethanol diacrylate and tetraethylene glycol diacrylate were used as crosslinkers, Irgacure® OXE01 was used as an initiator and methacryloxypropyltrimethoxysilane was used as an adhesion promoter.

RMR 2 was spin coated on top of the dielectric film of this example. The RMR layer was baked at 50° C. for 60 seconds on a hot plate to remove most of the solvent and to complete preparation of the stack of dielectric film and RMR layer of the example on top of a PVD-copper wafer. This is how a stack of dielectric film and RMR layer of the example is prepared on top of PVD-copper wafer. The RMR layer was exposed with a Canon i-line stepper (NA 0.45, SIGMA 0.7) through a trench test pattern reticle at a fixed dose of 500 mJ/cm² and −1 μm fixed focus. The exposed RMR layer was then developed by using 1-methoxy-2-propanol as solvent for 10 seconds to resolve trenches of dimensions of 50 μm and below including ultrafine 2 μm trench patterns as observed by an optical microscope. These 2 μm trench patterns were confirmed by cross-sectional scanning electron microscope (SEM). The thickness of the RMR layer after development was 0.31 μm. The ultrafine trench pattern was transferred to the dielectric film by etching with oxygen plasma for 15 minutes at Rf of 250 W and oxygen gas flow rate of 15 sccm.

The ultrafine trench patterns were then filled by electrodeposition of copper. The electrodeposition of copper was achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating was performed in a beaker while stirring using the following conditions: Anode: Copper; Plating Temperature: 25° C.; Current density: 10 mA/cm²; and Time: 2 minutes.

After completion of the process, copper lines of dimensions 50 μm and below were formed including fine 10 μm and ultrafine 2 μm copper lines. The dimensions of the fine and ultrafine copper lines were confirmed by optical microscope and cross-sectional SEM.

### Example 4: Fine and Ultrafine Cu Lines in Polycycloolefin Dielectric

A composition containing cyclolefin polymer (19.75 g, a 30/70 copolymer of 4′-bicyclo[2.2.1]hept-5-en-2-ylphenol, tetracyclo[4.4.0.12,5.17,10]dodec-3-en-8-ol), 10 wt % in PGMEA (U.S. Pat. No. 7,727,705), CLR-19-MF (3.08 g, supplied by Honshu Chemical Industries), 1-methoxy-2-propanol (24.90 g), Irgacure PAG 121 (0.10 g), and PGMEA (2.17 g) is spin-coated on a 100 mm PVD-copper wafer, is baked at 95° C. for 3 minutes using a hot plate, and is flood exposed with an i-line LED lamp at 500 mJ/cm². After exposure, the crosslinked polyolefin film is cured at 170° C. for 2 hour under vacuum to form a film thickness of about 3 μm.

The cyclolefin polymer (19.75 g, 10 wt %, a 30/70 copolymer of 4′-bicyclo[2.2.1]hept-5-en-2-ylphenol and tetracyclo[4.4.0.12,5.17,10]dodec-3-en-8-ol) is an example of a polycyclolefin dielectric polymer. CLR-19-MF is an example of a crosslinker, and Irgacure PAG 121 is used as a catalyst.

RMR 2 is spin coated on top of the dielectric film of this example. The RMR layer is baked at 50° C. for 60 seconds on a hot plate to remove most of the solvent and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench patterns as observed by an optical microscope. These 2 μm trench patterns are confirmed by cross-sectional scanning electron microscopy (SEM). The thickness of the RMR layer after development is 0.3 μm. The ultrafine trench pattern is transferred to the dielectric film by plasma etching.

The ultrafine trench patterns are then filled by electrodeposition of copper. The electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After completion of the process, copper lines of dimensions 50 μm and below are formed including fine 10 μm and ultrafine 2 μm copper lines. The dimensions of the fine and ultrafine copper lines are confirmed by optical microscope and cross-sectional SEM.

### Example 5: Fine and Ultrafine Cu Lines in Epoxy Dielectric

A formulation containing biphenyl-type epoxy resin (1.0 g, epoxy equivalent weight: 269, “NC3000H” supplied by NIPPON KAYAKU Co., Ltd.), spherical silica (5.0 g, “SOC2” supplied by Admatechs Co., Ltd.), Irgacure PAG 121 (0.10 g), methyl ethyl ketone (20 g) is spin-coated on a 100 mm PVD-copper wafer, is baked at 95° C. for 3 minutes using a hot plate, and is flood exposed with an i-line LED lamp at 500 mJ/cm². After exposure, the crosslinked dielectric film is cured at 170° C. for 2 hour under vacuum to form a film thickness of about 3 μm.

The biphenyl-type epoxy resin is an example of an epoxy polymer dielectric polymer. Spherical silica is an example of an inorganic particle, and Irgacure PAG 121 is used as a catalyst.

RMR 1 is spin coated on top of the dielectric film of this example. The RMR layer is baked at 50° C. for 60 seconds on a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench patterns as observed by an optical microscope These 2 μm trench patterns are confirmed by cross-sectional scanning electron microscope (SEM). The thickness of the RMR layer after development is 0.3 μm. The ultrafine trench pattern is transferred to the dielectric film by plasma etching.

The ultrafine trench patterns are then filled by electrodeposition of copper. The electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After completion of the process, copper lines of dimensions 50 μm and below are formed including fine 10 μm and ultrafine 2 μm copper lines. The dimensions of the fine and ultrafine copper lines are confirmed by optical microscope and cross-sectional SEM.

### Example 6: Fine and Ultrafine Cu Lines in Polyolefin and Filled Silica Dielectric

A formulation containing a cyclized rubber (SC Rubber supplied by Fujifilm Electronic Materials U.S.A., 12.0 g), tricyclodecanedimethanol diacrylate (2.5 g), Irgacure® OXE01 (0.5 g), methacryloxypropyltrimethoxysilane (0.8 g), silica (12.0 g, Silica nanoparticles SUPSIL™ PREMIUM, monodisperse, charge-stabilized supplied by Superior Silica), and xylene (51.7 g) is spin-coated on a 100 mm PVD-copper wafer, is baked at 95° C. for 6 minutes using a hot plate and is flood exposed with an i-line LED lamp at 500 mJ/cm². After exposure, the crosslinked dielectric film is cured at 170° C. for 2 hour under vacuum to form a film thickness of about 3 μm.

The cyclized rubber is used as an example of a polyolefin dielectric polymer. Silica nanoparticles are an example of an inorganic particle. Tricyclodecanedimethanol diacrylate is used as a crosslinker, Irgacure® OXE01 is used as an initiator and methacryloxypropyltrimethoxysilane is used as an adhesion promoter.

RMR 1 is spin coated on top of the dielectric film of this example. The RMR layer is baked at 50° C. for 60 seconds on a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench pattern as observed by an optical microscope. These 2 μm trench patterns are confirmed by cross-sectional scanning electron microscope (SEM). The thickness of the RMR layer after development is 0.5 μm. The ultrafine trench pattern is transferred to the dielectric film by means of plasma etching.

The ultrafine trench patterns are then filled by electrodeposition of copper. The electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After completion of the process, copper lines of dimensions 50 μm and below are formed including fine 10 μm and ultrafine 2 μm copper lines. The dimensions of the fine and ultrafine copper lines are confirmed by optical microscope and cross-sectional SEM.

### Preparation of RMR 3

An RMR composition is prepared by mixing hafnium carboxyethyl acrylate (30 g), Irgacure® OXE02 (0.9 g), butanol (20 g), 1-methoxy-2-propanol (18.0 g), and 1-methoxy-2-propyl acetate (31.1 g) to form a homogeneous solution. The solution is filtered by using a 0.2 micron PTFE filter.

### Example 7: Fine and Ultrafine Cu Lines in Polycycloolefin Dielectric

A formulation containing cycloolefin polymer (19.75 g, 10 wt %, a 30/70 copolymer of 4′-bicyclo[2.2.1]hept-5-en-2-ylphenol and tetracyclo[4.4.0.12,5.17,10]dodec-3-en-8-ol) in PGMEA (U.S. Pat. No. 7,727,705), CLR-19-MF (3.08 g, in 15 wt % solid in PGMEA), Irgacure PAG 121 (0.10 g), 12.0 g of silica (Silica nanoparticles SUPSIL™ PREMIUM, monodisperse, charge-stabilized available from Superior Silica), PGME (24.90 g), and PGMEA (2.17 g) is spin-coated on a 100 mm PVD-copper wafer, is baked at 95° C. for 3 minutes using a hot plate, and is flood exposed with a i-line LED lamp at 500 mJ/cm². After exposure, the crosslinked polyolefin film is cured at 170° C. for 2 hour under vacuum to form a film thickness of about 3 μm, thus providing a dielectric film containing a cycloolefin polymer.

The 30/70 copolymer of 4′-bicyclo[2.2.1]hept-5-en-2-ylphenol and tetracyclo[4.4.0.12,5.17,10]dodec-3-en-8-ol) is an example of a polycycloolefin dielectric polymer. CLR-19-MF is an example of a crosslinker, Irgacure PAG 121 is used as a catalyst, and silica is an example of an inorganic particle.

RMR 3 is spin coated on top of the dielectric film of this example. This film is then baked at 50° C. for 60 seconds using a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench patterns as observed by an optical microscope. These 2 μm trench patterns are confirmed by cross-sectional scanning electron microscopy (SEM). The thickness of the RMR layer after development is 0.3 μm. The ultrafine trench pattern is transferred to the dielectric film by means of plasma etching.

Electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate) (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After plating, the fine trenches are cut and the copper filling conditions are inspected using optical and scanning electron microscopes to confirm that the copper is completely filled without any voids. Also the time of deposition is controlled to avoid overburden.

### Example 8: Fine and Ultrafine Cu Lines in Polycycloolefin and Polyolefin Dielectric

A formulation containing a CYCLOTENE (10 g, which is a family of thermosetting polymer materials prepared from 1,3-divinyl-1,1,3,3-tetramethyldisiloxane-bisbenzocyclobutene (DVS-bis-BCB) monomer), a cyclized rubber (6.7 g), Sartomer SR833 (2.5 g), Sartomer SR268 (1.7 g), Irgacure® OXE01 (0.5 g, available from BASF), methacryloxypropyltrimethoxysilane (Gelest, 0.8 g), and xylene (51.7 g) is spin-coated on a 100 mm PVD-copper wafer, is baked at 115° C. for 6 minutes using a hot plate and is flood exposed with a i-line LED lamp at 500 mJ/cm². After exposure, the crosslinked polyolefin film is cured at 150° C. for 2 hour under vacuum to form a film thickness of about 3 μm.

The cyclotene and cyclized rubber are examples of polycyclolefin and polyolefin dielectric polymers. Tricyclodecanedimethanol diacrylate and tetraethylene glycol diacrylate are used as crosslinkers, Irgacure® OXE01 is used as an initiator, and methacryloxypropyltrimethoxysilane is used as an adhesion promoter.

The RMR forming composition of RMR 1 is spin coated on top of the dielectric film of this example. This film is then baked at 50° C. for 60 seconds using a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench patterns as observed by an optical microscope. These 2 μm trench patterns are confirmed by cross-sectional scanning electron microscopy (SEM). The thickness of the RMR layer after development is 0.3 μm. The ultrafine trench pattern is transferred to the dielectric film by means of plasma etching.

The wafer is then electroplated and 2 μm copper lines are produced in all trenches as observed by SEM. Electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 μm). Electroplating is performed in a beaker while stirring using the following conditions: Anode: Copper; Plating Temperature: 25° C.; Current density: 10 mA/cm²; and Time: 2 minutes.

After plating, the fine trenches are cut and the copper filling conditions are inspected using optical and scanning electron microscopes to confirm that the copper is completely filled without any voids. Also the time of deposition is controlled to avoid overburden.

### Example 9: Fine and Ultrafine Cu Lines in Polycycloolefin and Polyolefin Dielectric

A formulation containing a b-stage dicyclopentadiene thermoset resin (10 g), a cyclized rubber (6.7 g), tricyclodecanedimethanol diacrylate (2.5 g), tetraethylene glycol diacrylate (1.7 g), Irgacure® OXE01 (0.5 g), methacryloxypropyltrimethoxysilane (0.8 g), and xylene (51.7 g) is spin-coated on a 100 mm PVD-copper wafer. This formulation is then baked at 115° C. for 6 minutes using a hot plate and is flood exposed with a i-line LED lamp at 500 mJ/cm². After exposure, the crosslinked polyolefin film is cured at 150° C. for 2 hour under vacuum to form a film with thickness of about 3 μm.

The b-stage methacrylate-functionalized cycloolefin thermoset resin and cyclized rubber used here are the examples of polycyclolefin and polyolefin dielectric polymers. Tricyclodecanedimethanol diacrylate and tetraethylene glycol diacrylate are used as crosslinkers, Irgacure® OXE01 is used as an initiator, and methacryloxypropyltrimethoxysilane is used as an adhesion promoter.

RMR 1 is spin coated on top of the dielectric film of this example and is baked at 50° C. for 60 seconds using a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench pattern as observed by an optical microscope. These 2 μm trench patterns are confirmed by cross-section scanning electron microscope (SEM). The thickness of the RMR layer after development is 0.3 μm. The ultrafine trench pattern is transferred to the dielectric film by means of plasma etching.

Electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 μm). Electroplating is performed in a beaker while stirring using the following conditions: Anode: Copper; Plating Temperature: 25° C.; Current density: 10 mA/cm²; and Time: 2 minutes.

After plating, the fine trenches are cut and the copper filling conditions are inspected using optical and scanning electron microscopes to confirm that the copper is completely filled without any voids. Also the time of deposition is controlled to avoid overburden.

### Preparation of RMR 4

An RMR composition is prepared by mixing zirconyl dimethacrylate (30 g), NCI-831E supplied by Adeka Corporation (0.9 g), 1-methoxy-2-propanol (38.0 g) and 1-methoxy-2-propyl acetate (31.1 g) to form a homogeneous solution. The solution is filtered by using a 0.2 micron PTFE filter.

### Example 10: Fine and Ultrafine Cu Lines in Polycycloolefin and Polyolefin Dielectric

A formulation containing a b-stage methacrylate-functionalized cycloolefin thermoset resin (10 g), a cyclized rubber (6.7 g), tricyclodecanedimethanol diacrylate (2.5 g), tetraethylene glycol diacrylate (1.7 g), Irgacure® OXE01 (0.5 g), methacryloxypropyltrimethoxysilane (0.8 g), and xylene (51.7 g) is spin-coated on a 100 mm PVD-copper wafer. This formulation is then baked at 115° C. for 6 minutes using a hot plate and is flood exposed with an i-line LED lamp at 500 mJ/cm². After exposure the crosslinked polyolefin film is cured at 150° C. for 2 hour under vacuum to form a film with thickness of about 3 μm.

The b-stage methacrylate-functionalized cycloolefin thermoset resin and cyclized rubber used here are the examples of polycyclolefin and polyolefin dielectric polymers. Tricyclodecanedimethanol diacrylate and tetraethylene glycol diacrylate are used as crosslinkers, Irgacure® OXE01 is used as an initiator, and methacryloxypropyltrimethoxysilane is used as an adhesion promoter.

RMR 4 is spin coated on top of the dielectric film of this example and is baked at 50° C. for 60 seconds using a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench patterns as observed by an optical microscope. These 2 μm trench patterns are confirmed by cross-sectional scanning electron microscope (SEM). The ultrafine trench pattern is transferred to the dielectric film by means of plasma etching.

The wafer is then electroplated and 3 μm copper lines are produced in all trenches as observed by SEM. The thickness of the RMR layer after development is 0.3 μm. Electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 μm). Electroplating is performed in a beaker while stirring using the following conditions: Anode: Copper; Plating Temperature: 25° C.; Current density: 10 mA/cm²; and Time: 2 minutes.

After plating, the fine trenches are cut and the copper filling conditions are inspected using optical and scanning electron microscopes to confirm that the copper is completely filled without any voids. Also the time of deposition is controlled to avoid overburden.

### Example 11: Fine and Ultrafine Cu Lines in Polyolefin and Filled Silica Dielectric

A formulation containing a cyclized rubber (12.0 g), Sartomer SR833 (2.5 g), Irgacure® OXE01 (0.5 g), methacryloxypropyltrimethoxysilane (Gelest, 0.8 g), Primaset DT-4000 (12.0 g, available from Lonza Inc), silica (12.0 g, Silica nanoparticles SUPSIL™ PREMIUM, monodisperse and charge-stabilized available supplied by Superior Silica), and xylene (75.7 g) is spin-coated on a 100 mm PVD-copper wafer, is baked at 95° C. for 6 minutes using a hot plate, and is flood exposed with a i-line LED lamp at 500 mJ/cm². After exposure, the crosslinked polyolefin film is cured at 170° C. for 2 hours under vacuum to form a film thickness of about 3 μm.

The cyclized rubber is an example of a polyolefin dielectric polymer. Tricyclodecanedimethanol diacrylate and tetraethylene glycol diacrylate are examples of crosslinkers, Irgacure® OXE01 is an example of an initiator and methacryloxypropyltrimethoxysilane is an example of an adhesion promoter.

RMR 1 is spin coated on top of the dielectric film of this example. This film is then baked at 50° C. for 60 seconds using a hot plate to remove most of the solvent-and to complete preparation of the stack of dielectric film and RMR layer of the example on top of a PVD-copper wafer. The RMR layer is exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench pattern as observed by an optical microscope. These 2 μm trench patterns are confirmed by cross-sectional scanning electron microscope (SEM). The thickness of RMR layer after development is 0.3 μm. The ultrafine trench pattern is transferred to the dielectric film by means of plasma etching.

The wafer is then electroplated and 0.5 μm high copper lines are produced in all trenches as observed by SEM. Electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 μm). Electroplating is performed in a beaker while stirring using the following conditions: Anode: Copper; Plating Temperature: 25° C.; Current density: 10 mA/cm²; and Time: 2 minutes.

After plating, the fine trenches are cut and the copper filling conditions are inspected using optical and scanning electron microscopes to confirm that the copper is completely filled without any voids. Also the time of deposition is controlled to avoid overburden.

### Example 12: Process for Forming Fine and Ultrafine Copper Lines in Polyimide Based Dielectric Film

LTC 9320-E07 supplied by Fujifilm Electronic Materials USA containing a polyimide precursor polymer as dielectric polymer was spin coated on a 100 mm PVD-copper wafer and was baked at 115° C. for 6 minutes on a hot plate to remove most of the solvent. The resulting polyimide precursor dielectric film was flood exposed with an 8 W i-line LED lamp (UVP CL-1000L) at a dose of 600 mJ/cm². After exposure, the crosslinked polyimide precursor dielectric film was imidized at 400° C. for 1 hour under nitrogen to form a film thickness of 3.1 μm, thus providing a dielectric film containing a polyimide polymer. The dielectric constant value of this polyimide polymer was 3.2 and dielectric loss value was 0.02.

RMR 1 was spin coated on top of the dielectric film of this example. The RMR layer was baked at 50° C. for 60 seconds on a hot plate to remove most of the solvent and to complete preparation of the stack of dielectric film and RMR layer of the example on top of a PVD-copper wafer. The RMR layer was then exposed with a Canon i-line stepper (NA 0.45, SIGMA 0.7) through a trench test pattern reticle at a fixed dose of 500 mJ/cm² and −1 μm fixed focus. The exposed RMR layer was then developed by using 1-methoxy-2-propanol as solvent for 10 seconds to resolve trenches of dimensions of 50 μm and below including ultrafine 2 μm trench pattern as observed by an optical microscope. These 2 μm trench patterns were confirmed by cross-sectional scanning electron microscope (SEM). The thickness of the RMR layer after development was 0.6 μm. The ultrafine trench pattern was transferred to the dielectric film by etching with oxygen plasma for 25 minutes at Rf of 250 W and oxygen gas flow rate of 15 sccm.

The ultrafine trench patterns were then filled by electrodeposition of copper. The electrodeposition of copper was achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating was performed in a beaker while stirring using the following conditions: Anode: Copper; Plating Temperature: 25° C.; Current density: 10 mA/cm²; and Time: 2 minutes.

After completion of the process, a metal embedded dielectric stack was formed containing copper lines of dimensions 50 μm and below including fine 10 μm and ultrafine 2 μm copper lines. The dimensions of the fine and ultrafine copper lines were confirmed by optical microscope and cross-sectional SEM.

### Example 13: Process for Forming Multistacked Structures of Fine and Ultrafine Copper Lines in Polyimide Based Dielectric Film

LTC 9320-E07 supplied by Fujifilm Electronic Materials USA containing a polyimide precursor polymer as dielectric polymer is spin coated on a multi-stacked structure containing a silicon layer at the bottom, followed by a 100 micron thick layer of silicon oxide and a network of copper wires. The height of copper wires range from 5 to 7 microns and the width of copper wires range from 8 to 15 microns. The dielectric film is baked at 115° C. for 6 minutes on a hot plate to remove most of the solvent. The resulting film is flood exposed with an 8W i-line LED lamp (UVP CL-1000L) at a dose of 600 mJ/cm². After exposure, the crosslinked dielectric film is imidized at 400° C. for 1 hour under nitrogen to form a film thickness of 3.1 μm.

RMR 1 is spin coated on top of this dielectric film. The RMR layer is baked at 50° C. for 60 seconds on a hot plate to remove most of the solvent and to complete preparation of the stack of dielectric film and RMR layer of the example on top of the metal embedded dielectric stack. The RMR layer is then exposed with a Canon i-line stepper (NA 0.45, SIGMA 0.7) through a trench test pattern reticle at a fixed dose of 500 mJ/cm² and −1 μm fixed focus. The exposed RMR layer is then developed by using 1-methoxy-2-propanol as solvent for 10 seconds to resolve trenches of dimensions of 50 μm and below including ultrafine 2 μm trench pattern as observed by an optical microscope. These 2 μm trench patterns are confirmed by cross-sectional scanning electron microscope (SEM). The thickness of the RMR layer after development is 0.6 μm. The ultrafine trench pattern is transferred to the dielectric film by plasma etching.

The ultrafine trench patterns are then filled by electrodeposition of copper. The electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After completion of the process, copper lines of dimensions 50 μm and below are formed including fine 10 μm and ultrafine 2 μm copper lines. The dimensions of the fine and ultrafine copper lines are confirmed by optical microscope and cross-sectional SEM.

### Example 14: Fine Cu Filled Holes on Surface Mounted Chip

A polyimide polymer based dry film was produced by using Formulation Example (FE-1) and Dry Film Example (DF-1) as described in U.S. Patent Application No. 2018/0366419 except that the dry film thickness was 10.0 μm. The polyimide polymer dry film was laminated on a 300 mm silicon substrate with surface mounted chips. Lamination steps were performed in a vacuum laminator DPL-24A Differential Pressure Laminator manufactured by OPTEK, NJ and maintained at 100° C. top heater and 100° C. bottom heater. The lamination cycle included 20 seconds of vacuum dwell time and 180 seconds of pressure dwell time at an applied pressure of 50 psi. The polyimide polymer film was flood exposed with an i-line LED lamp at 500 mJ/cm² to form a film with a thickness of about 7 μm.

RMR 2 was spin coated on top of the dielectric film of this example. The RMR layer was baked at 50° C. for 180 seconds on a hot plate to remove most of the solvent. The stack of dielectric film and RMR layer of the example was prepared on top of a 300 mm silicon substrate with surface mounted chips. The RMR layer was exposed with a Broadband Mask Aligner MA-56 with a contact hole mask at an exposure dose of 500 mJ/cm². The exposed RMR layer was then developed by using 1-methoxy-2-propanol as solvent for 10 seconds to resolve fine holes of dimensions of 10 μm and below including 5 μm holes aligned to the surface mounted chips as observed by an optical microscope. The thickness of RMR layer after development is 1.0 μm. The pattern in the RMR layer was transferred to the dielectric film with oxygen plasma for 25 minutes at RF of 250 W and oxygen gas flow rate of 15 sccm.

The fine holes patterns were then filled by electrodeposition of copper. The electrodeposition of copper was achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating was performed in a beaker while stirring using the following conditions: Anode: Copper; Plating Temperature: 25° C.; Current density: 10 mA/cm²; and Time: 2 minutes.

After completion of the process, copper filled holes of dimensions 10 μm and below were formed including fine 5 μm copper filled holes. The dimensions of the fine copper holes were confirmed by optical microscope and cross-sectional SEM.

### Example 15: Process for Forming Ultrafine Trench Lines in Polycyanurate-Polyimide Based Dielectric Film Using Silicon Containing Resist Layer

A polycyanurate-polyimide based dielectric film-forming composition was prepared by using 100 parts of a 50% solution of BA-200 (i.e., 2,2-bis(4-cyanatophenyl)propane available from Lonza) in GBL, 17.65 parts of a 28.2% solution of a polyimide polymer P-1 (structure shown below) having a weight average molecular weight of 54,000 in GBL, 7.06 parts of a 0.5 wt % solution of PolyFox 6320 (available from OMNOVA Solutions) in GBL, 0.5 parts of zirconyl dimethacrylate (a cyanate curing catalyst), 0.09 parts of dicumyl peroxide, and 4.71 parts of 2-hydroxy-5-acrylyloxyphenyl-2H-benzotriazole. After being stirred mechanically for 24 hours, the solution was filtered by using a 0.2 micron filter (Ultradyne from Meissner Corporation, cat #CLTM0.2-552).

TIS1931L-A01 supplied by Fujifilm Electronic Materials USA was spin coated on top of the dielectric film of this example to form a silicon containing resist layer. The silicon containing resist layer was baked at 135° C. for 90 seconds on a hot plate to remove most of the solvent and to complete the preparation of the stack of dielectric film and silicon containing resist layer on top of a Si wafer. The silicon containing resist layer was then exposed with a Canon 248-nm stepper (NA 0.65, SIGMA 2 (Annular)) through a trench test pattern reticle 1 at a variable dose from 70 mJ/cm² to 85 mJ/cm² at 1 mJ/cm² intervals and variable focus −1.40 to 1.40 μm at 0.20 μm intervals. The exposed silicon containing resist layer was then baked at 125° C. for 90 seconds and was then developed by 2.38N TMAH for 60 seconds to resolve trenches of dimensions of 10 μm and below including ultrafine 2 μm trench patterns as observed by an optical microscope. These 2 μm trench patterns were confirmed by cross-sectional scanning electron microscopy (SEM). The thickness of the silicon containing resist layer after development was 0.60 μm. The wafer is cleaved into a 2 inch×2 inch square coupon. The ultrafine trench pattern was transferred to the dielectric film by etching with oxygen plasma for 5 minutes at Rf of 250 W and oxygen gas flow rate of 15 sccm.

After completion of the process, trenches of dimensions of 10 μm and below were formed including fine 10 μm and ultrafine 2 μm trenches in polycyanurate polyimide dielectric film. The dimensions of the fine and ultrafine trenches were confirmed by optical microscope.

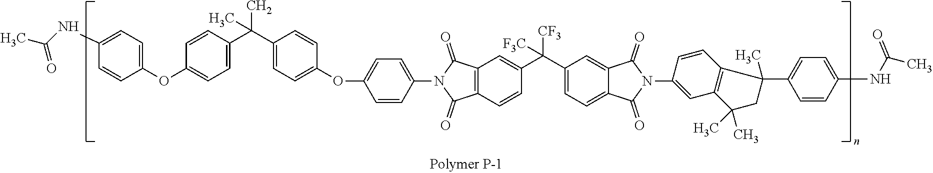

### Example 16: Process for Forming Ultrafine Copper Lines in Polycyanurate-Polyimide Based Dielectric Film Using Silicon Containing Resist Layer

The film forming composition of Example 14 is spin coated on a 200 mm Cu wafer and is baked at 120° C. for 6 minutes on a hot plate to remove most of the solvent. The resulting thermoset film is cyclized at 180° C. for 3 hours under nitrogen to form a film thickness of about 1.4 μm, thus providing a dielectric film containing a polycyanurate polyimide polymer.

TIS1931L-A01 supplied by Fujifilm Electronic Materials USA is spin coated on top of the dielectric film of this example to form a silicon containing resist layer. The silicon containing resist layer is baked at 135° C. for 90 seconds on a hot plate to remove most of the solvent and to complete the preparation of the stack of dielectric film and silicon containing resist layer on top of a PVD-copper wafer. The silicon containing resist layer is then exposed with a Canon 248-nm stepper (NA 0.65, SIGMA 2 (Annular)) through a trench test pattern reticle 1 at a fixed dose of 77 mJ/cm² and 0 μm fixed focus. The exposed silicon containing resist layer is then baked at 125° C. for 90 seconds and is then developed by 2.38N TMAH for 60 seconds to resolve trenches of dimensions of 10 μm and below including ultrafine 2 μm trench patterns as observed by an optical microscope. The wafer is cleaved into a 2 inch×2 inch square coupon. The ultrafine trench pattern is transferred to the dielectric film by etching with oxygen plasma for 5 minutes at Rf of 250 W and oxygen gas flow rate of 15 sccm.

The ultrafine trench patterns are then filled by electrodeposition of copper. The electrodeposition of copper is achieved using the electrolyte composition consisting of copper ion (30 g/L), sulfuric acid (50 g/L), chloride ion (40 ppm), poly(propylene glycol) (500 ppm), disodium 3,3-dithiobis(1-propanesulfonate (200 ppm), and bis(sodium sulfopropyl) disulfide (100 ppm). Electroplating is performed in a beaker while stirring using the following conditions: Anode: Copper; Plating Temperature: 25° C.; Current density: 10 mA/cm²; and Time: 2 minutes.

After completion of the process, copper lines of dimensions 10 μm and below are formed including fine 10 μm and ultrafine 2 μm copper lines in polyimide dielectric film. The dimensions of the fine and ultrafine copper lines are confirmed by optical microscope and cross-sectional SEM.

What is claimed is:

1. A process for depositing a conducting metal into a trench or hole, wherein the trench or hole is surrounded by a dielectric film, the process comprising:
a) providing a dielectric film;
b) depositing on top of the dielectric film a resist layer selected from the group consisting of a refractory metal resist layer and a silicon containing resist layer;
c) patterning the resist layer to form a pattern having a trench or hole using actinic radiation or an electron beam or x-ray;
d) transferring the pattern created in the resist layer to the underlying dielectric film by etching; and
e) filling the created pattern in the dielectric film with a conducting metal to form a dielectric film having a conducting metal filled trench or a conducting metal filled hole.

2. The process of claim 1, wherein the resist layer is a refractory metal resist layer.

3. The process of claim 1, wherein the resist layer is a silicon containing resist layer.

4. The process of claims 1, wherein the trench or hole has a dimension of at most about 10 microns.

5. The process of claims 1, wherein the trench or hole has a dimension of at most about 2 microns.

6. The process of claims 1, further comprising forming a multi-stacked structure comprising the dielectric film having a conducting metal filled trench or a conducting metal filled hole.

7. The process of claims 1, wherein the dielectric film has a dielectric loss of at most about 0.004.

8. The process of claims 1, wherein the resist layer is patterned in the light wavelength range of from about 13 nm to about 436 nm.

9. The process of claims 1, wherein the process does not remove the resist layer.

10. The process of claims 1, wherein the dielectric film comprises at least one polymer having a dielectric constant of at most about 4 and a dielectric loss of at most about 0.004.

11. The process of claim 2, wherein the refractory metal resist layer is prepared from a composition comprising:
a) at least one a metal-containing (meth)acrylate compound;
b) at least one solvent; and
c) at least one initiator.

12. The process of claim 11, wherein the at least one metal-containing (meth)acrylate compound has Structure I:
MR¹ₓR²_{y} (Structure I)
wherein
each R¹ is independently a (meth)acrylate-containing organic group;
each R² is independently selected from the group consisting of alkoxide, thiolate, alkyl, aryl, carboxy, β-diketonate, cyclopentadienyl and oxo;
x is 1, 2, 3, or 4, y is 0, 1, 2, or 3, and x+y=4; and
M is Ti, Zr or Hf.

13. The process of claim 11, wherein the at least one metal-containing (meth)acrylate comprises titanium tetra(meth)acrylate, zirconium tetra(meth)acrylate, hafnium tetra(meth)acrylate, titanium butoxide tri(meth)acrylate, titanium dibutoxide di(meth)acrylate, titanium tributoxide (meth)acrylate, zirconium butoxide tri(meth)acrylate, zirconium dibutoxide di(meth)acrylate, zirconium tributoxide (meth)acrylate, hafnium butoxide tri(meth)acrylate, hafnium dibutoxide di(meth)acrylate, hafnium tributoxide (meth)acrylate, titanium tetra(carboxyethyl (meth)acrylate), zirconium tetra(carboxyethyl (meth)acrylate), hafnium tetra(carboxyethyl (meth)acrylate), titanium butoxide tri(carboxyethyl (meth)acrylate), titanium dibutoxide di(carboxyethyl (meth)acrylate), titanium tributoxide (carboxyethyl (meth)acrylate), zirconium butoxide tri(carboxyethyl (meth)acrylate), zirconium dibutoxide di(carboxyethyl (meth)acrylate), zirconium tributoxide (carboxyethyl (meth)acrylate), hafnium butoxide tri(carboxyethyl (meth)acrylate), hafnium dibutoxide di(carboxyethyl (meth)acrylate), or hafnium tributoxide (carboxyethyl (meth)acrylate).

14. The process of claim 3, wherein the silicon containing layer is prepared from a composition comprising:
a) at least one silicon containing polymer;
b) at least one solvent; and
c) at least one photoacid generator.

15. The process of claim 1, wherein the resist layer is patterned by contact printing, stepper, scanner, laser direct imaging, or laser ablation.

16. The process of claim 1, wherein the dielectric film is prepared from a dielectric composition comprising at least one dielectric polymer, the dielectric polymer is selected from the group consisting of polyimides, polyimide precursor polymers, polybenzoxazoles, polybenzoxazole precursor polymers, polyamideimides, (meth)acrylate polymers, epoxy polymers, polyurethanes, polyamides, polyesters, polyethers, novolac resins, polycycloolefins, polyisoprene, polyphenols, polyolefins, benzocyclobutene resins, diamondoids, polystyrenes, polycarbonates, cyanate ester resins, polysiloxanes, copolymers and mixtures thereof.

17. A process for depositing a conducting metal into a trench or hole, wherein the trench or hole is surrounded by a dielectric film, the process comprising:
a) providing a dry film comprising a carrier substrate, a resist layer selected from the group consisting of a refractory metal resist (RMR) layer and a silicon containing resist layer, and a dielectric film, wherein the resist layer is between the carrier substrate and the dielectric film;
b) laminating the dry film onto a semiconductor substrate such that the dielectric film is between the semiconductor substrate and the resist layer;
c) removing the carrier substrate;
d) patterning the resist layer to form a pattern having a trench or hole using actinic radiation or an electron beam or x-ray;
e) transferring the pattern created in the resist layer to the underlying dielectric film by etching; and
f) filling the created pattern in the dielectric film with a conducting metal to form a dielectric film having a conducting metal filled trench or a conducting metal filled hole.

18. The process of claim 17, wherein the resist layer is a refractory metal resist layer.

19. The process of claim 17, wherein the resist layer is a silicon containing resist layer.

20. The process of claims 17, wherein the trench or hole has a dimension of at most about 10 microns.

21. The process of claims 17, wherein the trench or hole has a dimension of at most about 2 microns.

22. The process of claims 17, further comprising forming a multi-stacked structure comprising the dielectric film having a conducting metal filled trench or a conducting metal filled hole.

23. The process of claims 17, wherein the dielectric film has a dielectric loss of at most about 0.004.

24. The process of claims 17, wherein the resist layer is patterned in the light wavelength range of from about 13 nm to about 436 nm.

25. The process of claims 17, wherein the process does not remove the resist layer.

26. The process of claims 17, wherein the dielectric film comprises at least one polymer having a dielectric constant of at most about 4 and a dielectric loss of at most about 0.004.

27. The process of claim 18, wherein the refractory metal resist layer is prepared from a composition comprising:
a) at least one a metal-containing (meth)acrylate compound;
b) at least one solvent; and
c) at least one initiator.

28. The process of claim 27, wherein the at least one metal-containing (meth)acrylate compound has Structure I:
MR¹ₓR²_{y} (Structure I)
wherein
each R¹ is independently a (meth)acrylate-containing organic group;
each R² is independently selected from the group consisting of alkoxide, thiolate, alkyl, aryl, carboxy, β-diketonate, cyclopentadienyl and oxo;
x is 1, 2, 3, or 4, y is 0, 1, 2, or 3, and x+y=4; and
M is Ti, Zr or Hf.

29. The process of claim 27, wherein the at least one metal-containing (meth)acrylate comprises titanium tetra(meth)acrylate, zirconium tetra(meth)acrylate, hafnium tetra(meth)acrylate, titanium butoxide tri(meth)acrylate, titanium dibutoxide di(meth)acrylate, titanium tributoxide (meth)acrylate, zirconium butoxide tri(meth)acrylate, zirconium dibutoxide di(meth)acrylate, zirconium tributoxide (meth)acrylate, hafnium butoxide tri(meth)acrylate, hafnium dibutoxide di(meth)acrylate, hafnium tributoxide (meth)acrylate, titanium tetra(carboxyethyl (meth)acrylate), zirconium tetra(carboxyethyl (meth)acrylate), hafnium tetra(carboxyethyl (meth)acrylate), titanium butoxide tri(carboxyethyl (meth)acrylate), titanium dibutoxide di(carboxyethyl (meth)acrylate), titanium tributoxide (carboxyethyl (meth)acrylate), zirconium butoxide tri(carboxyethyl (meth)acrylate), zirconium dibutoxide di(carboxyethyl (meth)acrylate), zirconium tributoxide (carboxyethyl (meth)acrylate), hafnium butoxide tri(carboxyethyl (meth)acrylate), hafnium dibutoxide di(carboxyethyl (meth)acrylate), or hafnium tributoxide (carboxyethyl (meth)acrylate).

30. The process of claim 19, wherein the silicon containing layer is prepared from a composition comprising:
a) at least one silicon containing polymer;
b) at least one solvent; and
c) at least one photoacid generator.

31. The process of claim 17, wherein the resist layer is patterned by contact printing, stepper, scanner, laser direct imaging, or laser ablation.

32. The process of claim 17, wherein the dielectric film is prepared from a dielectric composition comprising at least one dielectric polymer, the dielectric polymer is selected from the group consisting of polyimides, polyimide precursor polymers, polybenzoxazoles, polybenzoxazole precursor polymers, polyamideimides, (meth)acrylate polymers, epoxy polymers, polyurethanes, polyamides, polyesters, polyethers, novolac resins, polycycloolefins, polyisoprene, polyphenols, polyolefins, benzocyclobutene resins, diamondoids, polystyrenes, polycarbonates, cyanate ester resins, polysiloxanes, copolymers and mixtures thereof.
